(19) United States
(12) Patent Application Publication
(10) Pub. No.: US 2025/0140014 A1
(43) Pub. Date: May 1, 2025

(54) DRAWING RECOGNITION SYSTEM AND DRAWING RECOGNITION METHOD

(71) Applicant: NOHARA GROUP, INC., Tokyo (JP)

(72) Inventor: Masahiro HIGASHI, Tokyo (JP)

(21) Appl. No.: 18/835,303

(22) PCT Filed: Mar. 23, 2023
(86) PCT No.: PCT/JP2023/011535

§ 371 Date: Aug. 1, 2024

(30) Foreign Application Priority Data
Mar. 25, 2022 (JP) 2022-049929

(51) Int. Cl. G06V 30/422; G06V 10/26; G06V 10/764; G06V 10/98; G06V 30/413

(52) U.S. Cl. CPC G06V 30/422; G06V 10/26; G06V 10/764; G06V 10/98; G06V 30/413

(57) ABSTRACT

To improve recognition accuracy of a plan view of a building. A drawing recognition system 10 includes: an acquisition unit 11 for acquiring drawing data including a plan view of a building; a dividing unit 13 for generating divided drawings by dividing the plan view based on a number of rooms included in the plan view; a recognition unit 14 for generating a recognition result of the plan view by recognizing an element included in the plan view based on the divided drawings; and an output unit 15 for outputting the recognition result of the plan view.

### CROSS REFERENCE TO RELATED APPLICATIONS

This application is a national phase of International Application No. PCT/JP2023/011535 filed Mar. 23, 2023 and claims priority to Japanese Patent Application No. 2022-049929 entitled “DRAWING RECOGNITION SYSTEM AND DRAWING RECOGNITION METHOD” filed on Mar. 25, 2022, the disclosure of which is incorporated herein by reference in its entirety.

### BACKGROUND

The present disclosure relates to a drawing recognition system and a drawing recognition method.

A machine learning model “Deep Floor Plan” constituted by carrying out machine learning using plan views of simple houses is disclosed in non-patent document 1. The machine learning model recognizes elements included in an inputted plan view of a building.

### CITATION LIST

### Non Patent Literature

NPL 1: Zhiliang Zeng, Xianzhi Li, Ying Kin Yu, Chi-Wing Fu, “Deep Floor Plan Recognition Using a Multi-Task Network with Room-Boundary-Guided Attention,” The Chinese University of Hong Kong, Aug. 29, 2019

### SUMMARY

There are plan views (or floor plans) of small-scale buildings such as detached houses, in addition to plan views of large-scale buildings such as hospitals, apartment houses, and hotels. When an attempt is made to recognize elements included in a plan view of a building which is different in scale, there is a possibility that accurate recognition result may not be obtained. In the technical field, it is desirable that elements included in plan views of various types of buildings are accurately recognized.

The present disclosure describes a drawing recognition system and a drawing recognition method which are capable of improving recognition accuracy of a plan view of a building.

A drawing recognition system according to an aspect of the present disclosure includes: an acquisition unit for acquiring drawing data including a plan view (or floor plan) of a building; a dividing unit for generating divided drawings (or divided figures) by dividing the plan view based on a number of rooms included in the plan view; a recognition unit for generating a recognition result of the plan view by recognizing an element(s) included in the plan view based on the divided drawings; and an output unit for outputting the recognition result of the plan view.

A drawing recognition method according to another aspect of the present disclosure includes: a step for acquiring drawing data including a plan view of a building; a step for generating divided drawings by dividing the plan view based on a number of rooms included in the plan view; a step for generating a recognition result of the plan view by recognizing an element(s) included in the plan view based on the divided drawings; and a step for outputting the recognition result of the plan view.

According to the drawing recognition system and the drawing recognition method, a plan view is divided based on the number of rooms included in the plan view, and an element(s) included in the plan view is recognized based on the divided drawings. According to this configuration, even in a case of a plan view of a building with a different scale, variations in the number of rooms included in the divided drawing may be suppressed because the number of rooms is taken into consideration when the plan view is divided. Therefore, it is possible to improve the recognition accuracy of the elements included in the divided drawings. As a result, the recognition accuracy of the plan view of the building may be improved.

In some embodiments, the recognition unit may be provided with a recognition model that is generated by carrying out machine learning using a plurality of plan views as learning data. The recognition model may be configured to receive the divided drawings and to output recognition results of the divided drawings. In this case, it is possible to improve the recognition accuracy of the plan view of the building by carrying out the learning processes of the recognition model with a sufficient amount of plan views.

In some embodiments, the drawing recognition system may further include a classification unit for classifying the plan view into one of a plurality of types. With respect to the above-mentioned recognition model, the recognition unit may include a plurality of recognition models corresponding to the plurality of types. The recognition unit may be configured to select a recognition model from among the plurality of recognition models according to the type of the plan view, and to generate the recognition result of the plan view by use of the selected recognition model. In this case, one or a plurality of elements included in the divided drawing are recognized by using a recognition model corresponding to the type of the plan view. According to this configuration, it is possible to improve the recognition accuracy of the plan view as compared with a configuration in which a plurality of types of plan views are recognized by using a general-purpose recognition model.

In some embodiments, the classification unit may determine whether the plan view is a drawing ensuring accuracy of drawing recognition (or a drawing which is capable of ensuring accuracy of drawing recognition) or a drawing not ensuring accuracy of drawing recognition (or a drawing which is not capable of ensuring accuracy of drawing recognition). If the plan view is determined to be a drawing not ensuring accuracy of drawing recognition, the recognition unit may refrain from recognizing an element(s) included in the plan view. According to this configuration, one or a plurality of drawings not ensuring accuracy of drawing recognition are excluded from the recognition objects, and accordingly, it becomes possible to avoid decline in the drawing recognition of the plan view.

In some embodiments, if the plan view is determined to be a drawing not ensuring accuracy of drawing recognition, the output unit may output information indicating that the plan view is not subject to the drawing recognition. For example, a user may be made to be recognized that the plan view is not subject to the drawing recognition, by notifying the user of information indicating that it is exempt from the objects of the drawing recognition.

In some embodiments, the dividing unit may generate a binarized image by binarizing the plan view, to calculate the number of rooms based on an object(s) in a white-colored area(s) included in the binarized image. In this case, the number of rooms is obtained by performing image processing on the plan view. Therefore, it is possible to generate divided drawings from the plan view without using other information.

In some embodiments, the dividing unit may divide the plan view so that the number of rooms included in the divided drawing is equal to or less than a predetermined number. In this case, even if a plurality of rooms are included in the plan view, the divided drawing is made to include rooms of which number is not more than a predetermined number. Accordingly, even in a case of a plan view of a building with a different scale, variations in the number of rooms included in the divided drawing may be suppressed. As a result, it is possible to improve the recognition accuracy of the plan view of the building.

According to the present disclosure, it is possible to improve recognition accuracy of a plan view of a building.

### BRIEF DESCRIPTION OF DRAWINGS

FIG. 1 is a block diagram illustrating an example of a functional configuration of a drawing recognition system according to an embodiment;

FIG. 2 is a diagram illustrating an example of a hardware configuration of a computer constituting the drawing recognition system illustrated in FIG. 1;

FIG. 3 is a diagram for explaining a selection of a plan view, which is to be carried out by a user;

FIG. 4 is a diagram for explaining an input of index lines of an outer periphery and actual size values of a building, which is to be carried out by a user;

FIG. 5 is a flowchart of a drawing recognition method, which is to be carried out by the drawing recognition system illustrated in FIG. 1;

FIG. 6 is a flowchart illustrating an example of the classification process of FIG. 5 in detail;

FIG. 7 is a diagram for describing a detection process of an oblique room;

FIG. 8 is a flowchart illustrating an example of the dividing process of FIG. 5 in detail;

FIG. 9 is a diagram for explaining the dividing procedure of a plan view;

FIG. 10 is a diagram for explaining the recognition process;

FIG. 11 is a diagram illustrating an example of a recognition result of a plan view; and

FIG. 12 is a diagram illustrating a different example of a recognition result of a plan view.

### DESCRIPTION OF EMBODIMENTS

Hereinafter, embodiments of the present disclosure will be described in detail with referring to the figures. In the descriptions on the figures, the same elements are denoted by the same reference numerals, and redundant descriptions will be omitted.

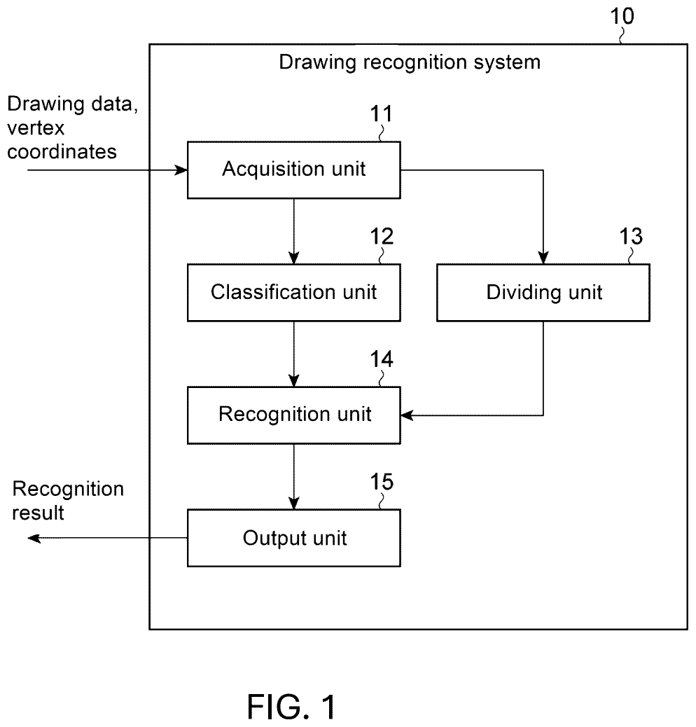

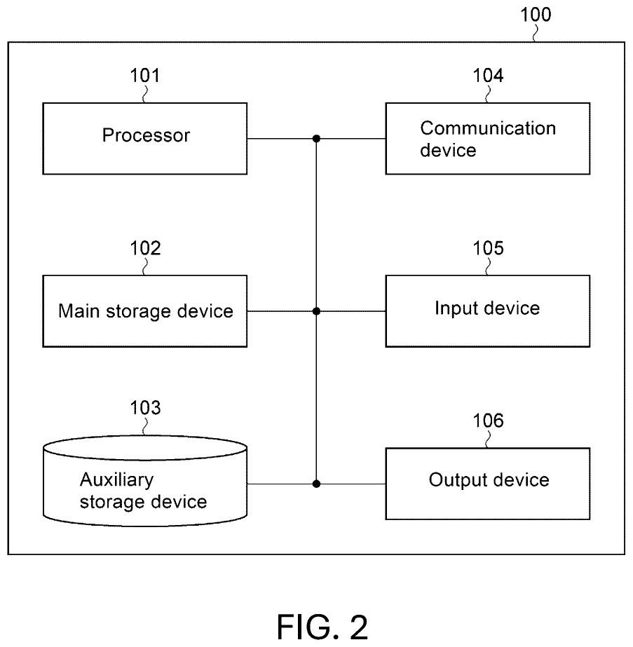

At first, a drawing recognition system according to an embodiment will be described with referring to FIGS. 1 and 2.

FIG. 1 is a block diagram illustrating an example of a functional configuration of a drawing recognition system according to an embodiment.

FIG. 2 is a diagram illustrating an example of a hardware configuration of a computer constituting the drawing recognition system illustrated in FIG. 1.

The drawing recognition system 10 illustrated in FIG. 1 is configured as a system for recognizing an element(s) included in a plan view of a building. Examples of the building include detached houses, apartment houses, hospitals, clinics, hotels, and welfare facilities. Examples of the element include rooms, walls, and openings. The drawing recognition system 10 is configured to receive drawing data including a plan view (or floor plan) from a terminal device of a user via a communication network. The communication network may be configured by any of wired and wireless networks. For example, the communication network may include the Internet, the WAN (Wide Area Network), and the mobile communication network.

The drawing recognition system 10 may be configured by a single computer 100 (see FIG. 2). Alternatively, the drawing recognition system 10 may be configured by a plurality of computers 100 such as the case of cloud computing. In the latter case, a plurality of computers 100 are connected to each other via a communication network so as to mutually communicate. As a result, a plurality of computers 100 are capable of functioning as one drawing recognition system 10 logically.

As illustrated in FIG. 2, the computer 100 includes a processor 101, a main storage device 102, an auxiliary storage device 103, a communication device 104, an input device 105, and an output device 106.

Examples of the processor 101 include a CPU (or Central Processing Unit).

The main storage device 102 is consisting of a RAM (or Random Access Memory) and a ROM (or Read Only Memory), etc. Examples of the auxiliary storage device 103 include a semiconductor memory and a hard disk device. Examples of the communication device 104 include a network card and a wireless communication module. Examples of the input device 105 include a keyboard and a mouse. Examples of the output device 106 include a display. However, the computer 100 may not be always provided with the input device 105 and the output device 106.

Each functional element (or functional component) of the drawing recognition system 10 is realized by causing a hardware such as the processor 101 or the main storage device 102 to read a predetermined computer program and causing the processor 101 to execute the computer program. The processor 101 operates each hardware in accordance with the computer program to read and write data stored in the main storage device 102 and the auxiliary storage device 103.

As illustrated in FIG. 1, the drawing recognition system 10 includes an acquisition unit 11, a classification unit 12, a dividing unit 13, a recognition unit 14, and an output unit 15, as the functional elements. In the following descriptions of a way of recognizing a drawing (or figure), the functions (or operations) of the respective functional elements will be described in detail, and therefore, the functions of the respective functional elements will be briefly described here.

The acquisition unit 11 is a functional element for acquiring various types of data. For example, the acquisition unit 11 acquires drawing data including a plan view from a terminal device of a user via a communication network.

The classification unit 12 is a functional element for classifying a plan view into one of a plurality of types (or kinds). For example, the classification unit 12 classifies a plan view into one of a drawing including an oblique room, a drawing not including an oblique room, and a drawing not ensuring accuracy of drawing recognition. Examples of a drawing not ensuring accuracy of drawing recognition include a drawing having a low resolution, a drawing having a low image quality, a drawing covered with diagonal lines (or oblique lines), a drawing having a grayed out room, and a drawing having a partition drawn by dotted-lines.

The dividing unit 13 is a functional element for generating divided drawings by dividing a plan view according to the number of rooms which are included in the plan view. The dividing unit 13 divides a plan view such that the number of rooms included in each divided drawing is made to be equal to or less than a predetermined number (which corresponds to a reference number of rooms N_{ref}, as discussed below.). The predetermined number is, for example, 20.

The recognition unit 14 is a functional element for generating a recognition result of the plan view by recognizing one or a plurality of elements included in the plan view based on the divided drawings. The recognition unit 14 includes a plurality of recognition models corresponding to a plurality of types classified by the classification unit 12. Each recognition model is generated by carrying out machine learning using a plurality of plan views of a type corresponding to the recognition model as learning data. Each recognition model is configured to receive divided drawings and to output recognition results of the divided drawings. The recognition unit 14 selects one recognition model according to a type of the plan view obtained by the acquisition unit 11 among a plurality of recognition models, and generates a recognition result of the plan view by use of the selected recognition model.

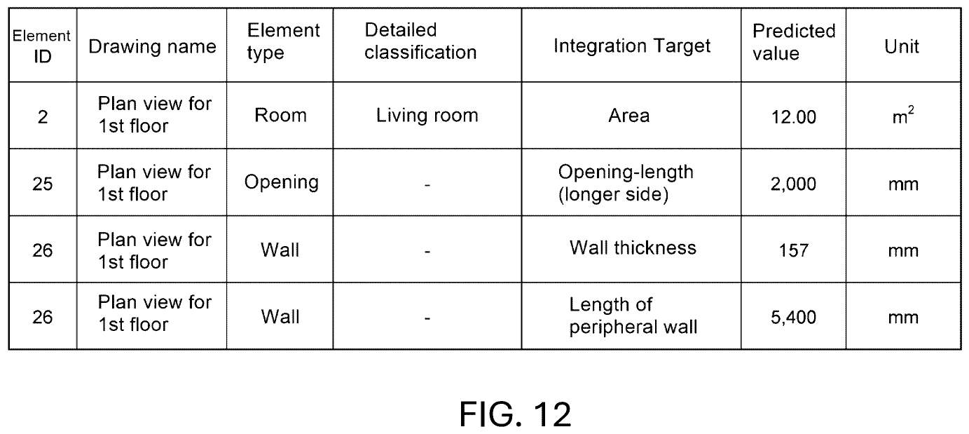

For example, a recognition result of a plan view includes an element ID, a drawing name, an element type, a detailed classification, an integration target, a predicted value and its unit (see FIG. 12). The element ID is information capable of uniquely identifying an element. The element type indicates a type of an element such as a room, an opening, and a wall. The detailed classification is a classification obtained by subdividing the element type. For example, a room may be subdivided into a living room or the like. The integration target is a parameter for defining sizes of an element. The predicted value is a value of an integration target obtained by the drawing recognition. The unit is a unit used for obtaining the predicted value.

The output unit 15 is a functional element for outputting a recognition result of a plan view. For example, the output unit 15 outputs (or transmits) a recognition result of a plan view to a terminal device of a user by using an electronic mail.

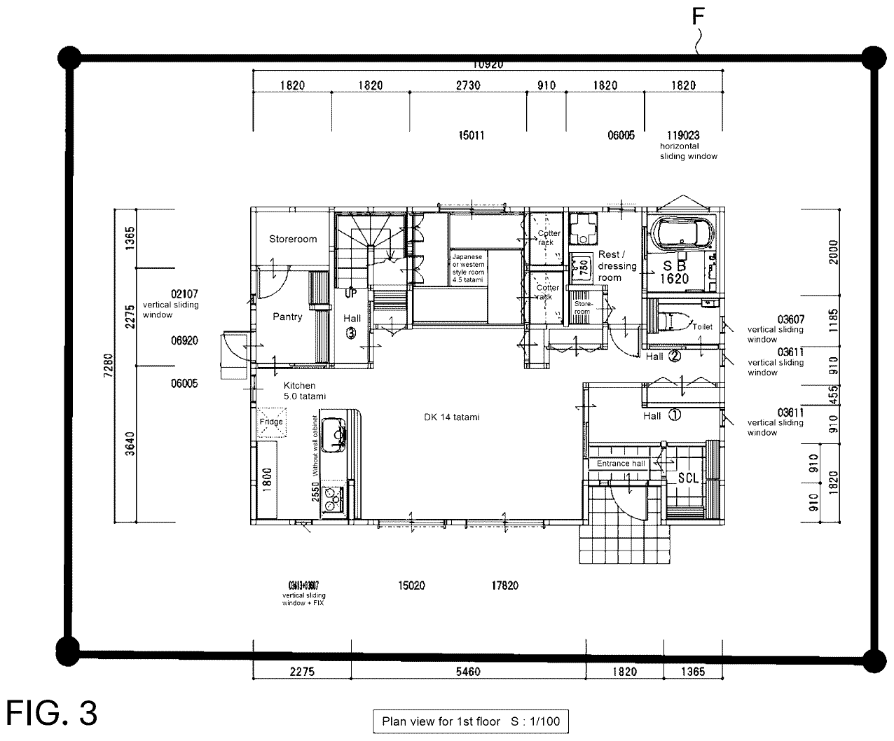

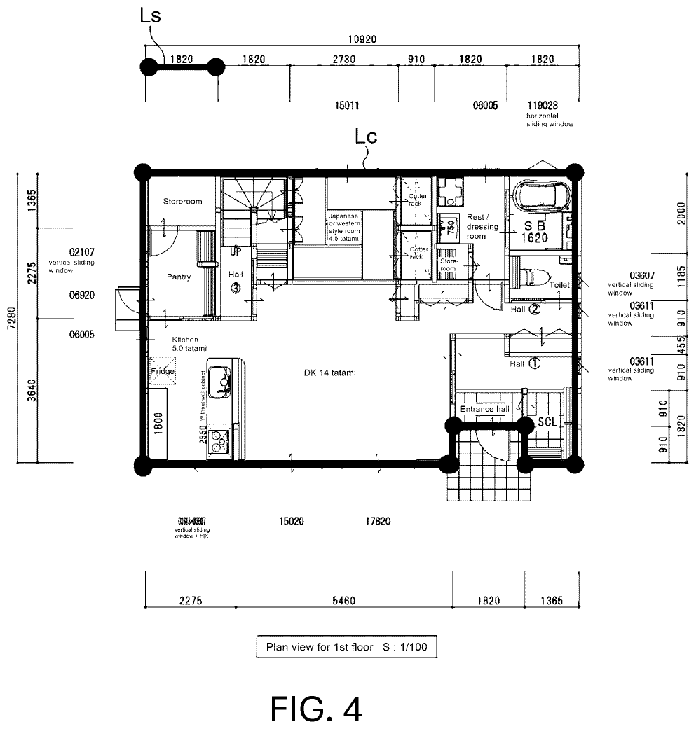

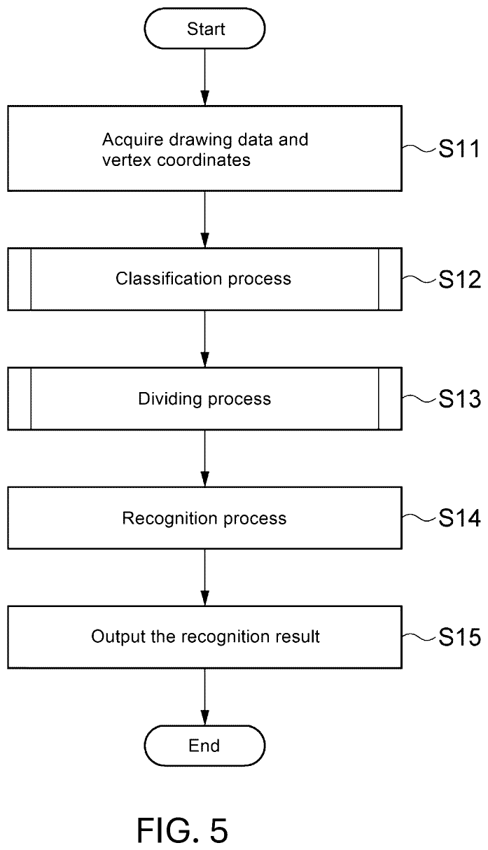

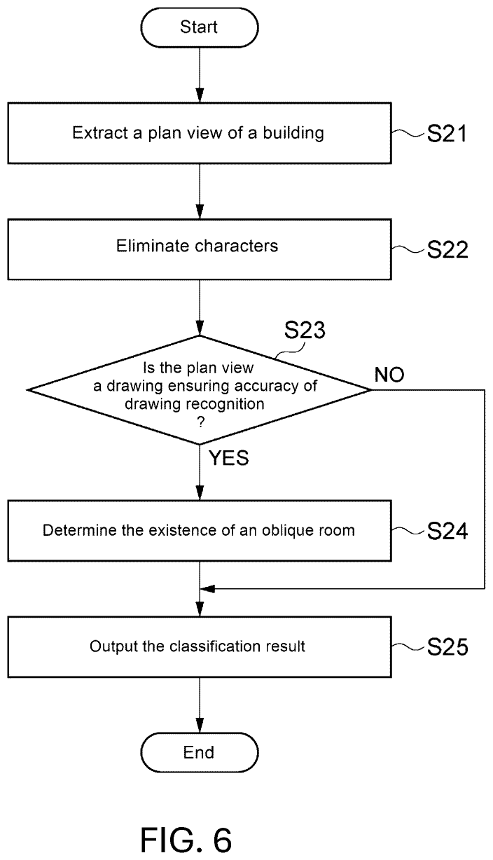

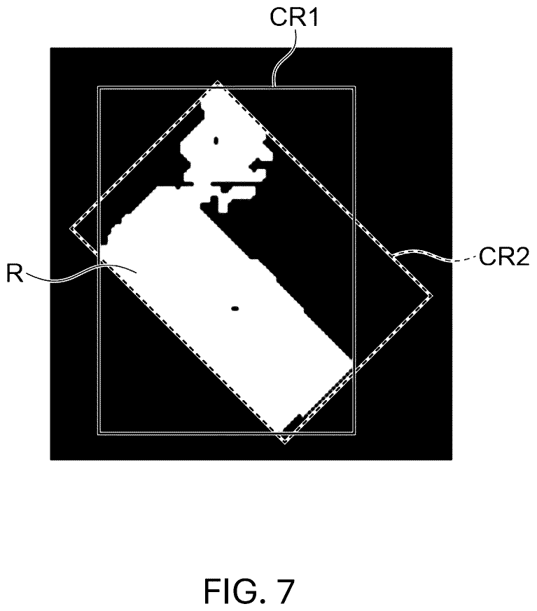

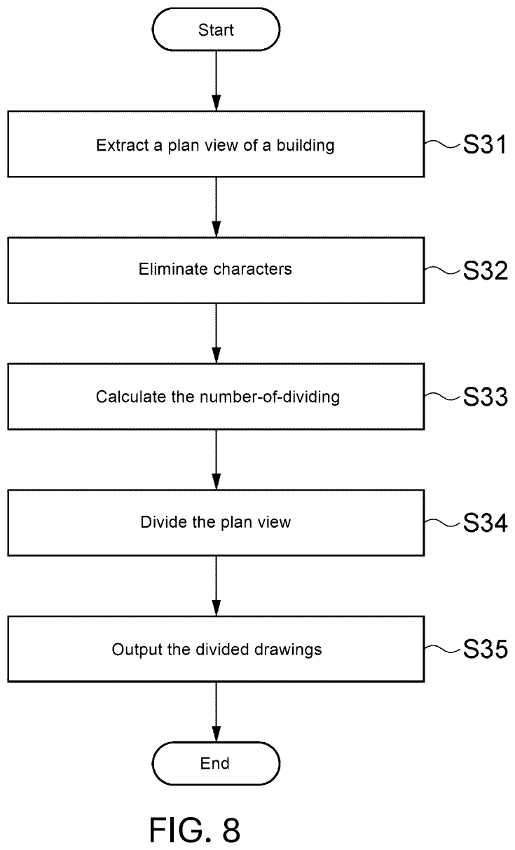

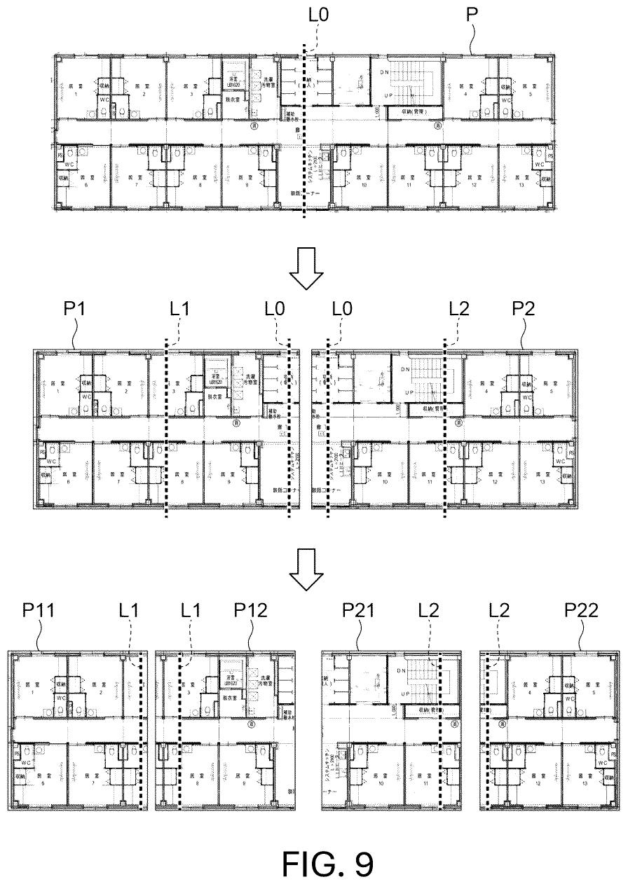

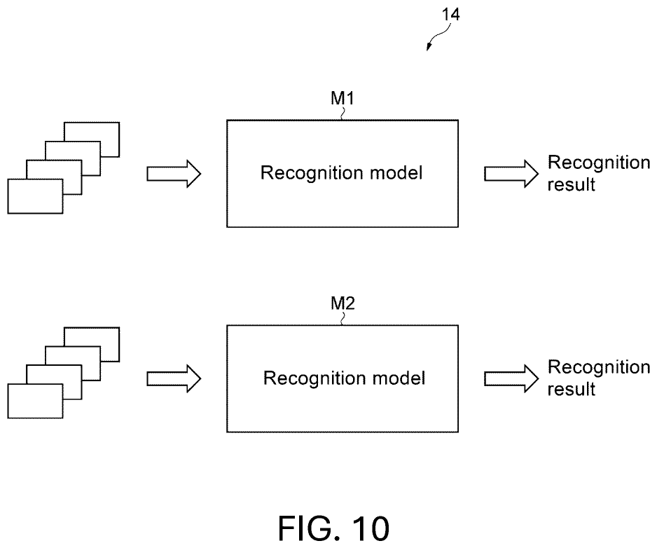

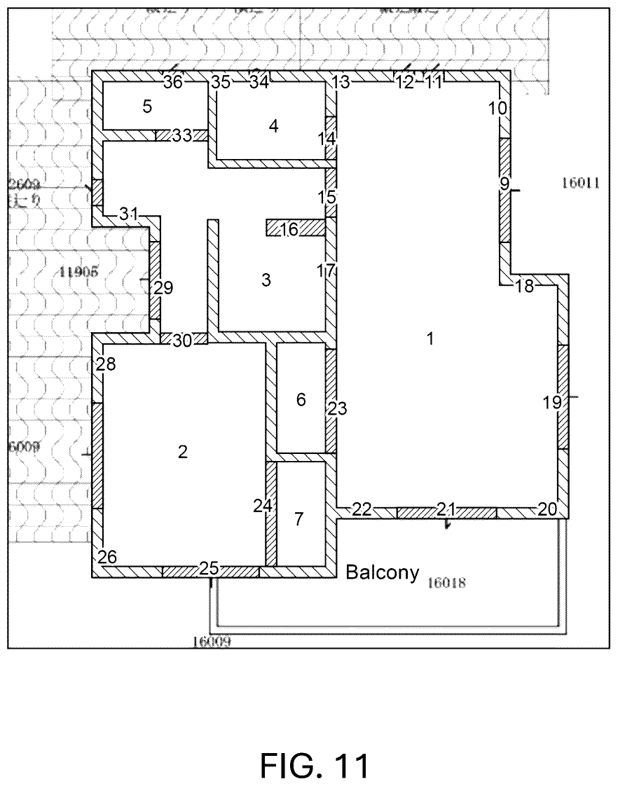

Followingly, a way of recognizing a drawing which is to be carried out by the drawing recognition system 10 will be described with referring to FIGS. 3 to 12. FIG. 3 is a diagram for explaining a selection of a plan view, which is to be carried out by a user. FIG. 4 is a diagram for explaining an input of index lines of an outer periphery and actual size values of a building, which is to be carried out by a user. FIG. 5 is a flowchart of a drawing recognition method, which is to be carried out by the drawing recognition system illustrated in FIG. 1. FIG. 6 is a flowchart illustrating an example of the classification process of FIG. 5 in detail. FIG. 7 is a diagram for explaining a detection process of an oblique room. FIG. 8 is a flowchart illustrating an example of the dividing process of FIG. 5 in detail. FIG. 9 is a diagram for explaining the dividing procedure of a plan view. FIG. 10 is a diagram for explaining the recognition process. FIG. 11 is a diagram illustrating an example of a recognition result of a plan view. FIG. 12 is a diagram illustrating a different example of a recognition result of a plan view.

At the use of a drawing recognition application, firstly, a user uploads desired drawing data and then selects a plan view included in the drawing data. The drawing recognition application is, for example, a web application. The drawing data is, for example, a PDF (Portable Document Format) file. For example, as illustrated in FIG. 3, a user selects a plan view as a recognition object by surrounded the plan view (which is included in the drawing data) by a rectangular frame F. The frame F contains information of sizes and the like in addition to the plan view of the building.

Subsequently, a user inputs index lines of the outer circumference and the actual size values of the building which is included in the selected plan view. For example, as illustrated in FIG. 4, a user draws a line(s) Lc along an outer wall of the building so as to surround the building, thereby inputting the outer periphery of the building. In addition, a user draws an index line(s) Ls representing the length of the actual size value on the drawing, and inputs the actual size value represented by the index line Ls.

The terminal device calculates the vertex coordinates of the outer periphery of the building upon receiving the above-mentioned input, and transmits the drawing data and the vertex coordinates of the outer periphery to the drawing recognition system 10. This leads to a starting of a series of processes illustrated in FIG. 5.

As illustrated in FIG. 5, at first, the acquisition unit 11 acquires drawing data, vertex coordinates of the frame indicating the plan view, and vertex coordinates of the outer periphery (step S11). Subsequently, the acquisition unit 11 outputs the drawing data, the vertex coordinates of the frame indicating the plan view, and the vertex coordinates of the outer periphery to the classification unit 12 and the dividing unit 13.

Subsequently, the classification unit 12 performs a classification process (step S12). As illustrated in FIG. 6, during the course of the classification process at the step S12, the classification unit 12 extracts a plan view of a building when it receives the drawing data, the vertex coordinates of the frame indicating the plan view, and the vertex coordinates of the outer periphery (step S21). For example, the classification unit 12 finds out the minimum value and the maximum value of the X coordinate and the minimum value and the maximum value of the Y coordinate from the vertex coordinates of the outer periphery, and then calculates the lower left coordinate (or the minimum value of the X coordinate and the minimum value of the Y coordinate) and the upper right coordinate (or the maximum value of the X coordinate and the maximum value of the Y coordinate). Followingly, the classification unit 12 extracts a range of the rectangular shape which is constituted of the diagonal vertexes based on the lower left and upper right coordinates, as the plan view of the building, from the drawing data.

Subsequently, the classification unit 12 eliminates or removes characters (or letters) from the extracted plan view (step S22). For example, the classification unit 12 binarizes the plan view and then detects one or a plurality of continuous areas satisfying a predetermined condition, as a character area(s). The continuous area is an area in which black pixels are continuous. Followingly, the classification unit 12 eliminates one or a plurality of character areas from the binarized plan view and then generates a binarized image.

Subsequently, the classification unit 12 determines whether the plan view is a drawing ensuring accuracy of drawing recognition or a drawing not ensuring accuracy of drawing recognition (step S23). In this example, the following descriptions will be given using a drawing having a low resolution (or, a drawing having a coarse image) and a drawing covered with diagonal lines as the examples of the drawing not ensuring accuracy of drawing recognition.

At first, the classification unit 12 detects contour points, straight lines, and diagonal lines (or hatched lines) included in the binarized image. For example, contour points are detected by use of the module, “findContours” of the Open CV (or Open Source Computer Vision Library). In a case where the detected contour points are consecutive, a contour line is generated. For example, straight lines are detected by use of the modular, “HoughLinesP” of the Open CV. For example, diagonal lines are detected by providing a kernel (or filter) of diagonal lines on the binarized image, and by performing morphology operation by use of the modules, “dilate” and “erode” of the Open CV.

Followingly, the classification unit 12 calculates the score of the resolution and the score of the coverage ratio of the diagonal lines by using the contour points, the straight lines, and the diagonal lines. For example, the classification unit 12 obtains nine image areas by equally dividing the binarized image into three along the vertical direction (Y axis direction) and into three along the horizontal direction (X axis direction), and then calculates the scores for the respective image areas.

Subsequently, an example of a way of calculating the score of the coverage ratio of the diagonal lines will be described. The score of the coverage ratio of the diagonal lines is set to the initial value (or zero). The classification unit 12 finds out a ratio of the number of pixels occupied by all the detected diagonal lines in relation to the number of pixels occupied by all the detected contour lines, and then compares the obtained ratio with a predetermined threshold value Dth (for example, 0.25). In a case where the ratio is equal to or larger than the threshold value Dth, the classification unit 12 determines that the coverage ratio of the diagonal lines is large, and then adds a predetermined point to the score of the coverage ratio of the diagonal lines. Alternatively, in a case where the ratio is less than the threshold value Dth, the classification unit 12 determines that the coverage ratio of the diagonal lines is small, and does not add a point to the score of the coverage ratio of the diagonal lines. As described above, the score of the coverage ratio of the diagonal lines is calculated.

Subsequently, an example of a way of calculating the score of the resolution will be described. The resolution score is set to the initial value (or zero). In a case of an image having a low resolution, many contour points tend to be detected. Accordingly, the classification unit 12 calculates a ratio of the number of pixels occupied by all the detected contour points in relation to the number of pixels occupied by all the detected contour lines, and then compares the obtained ratio with a predetermined threshold value Rth1 (for example, 1.5). In a case where the ratio is equal to or larger than the threshold value Rth1, the classification unit 12 determines that the resolution is low and then adds a predetermined point to the score of the resolution. Alternatively, in a case where the ratio is less than the threshold value Rth1, the classification unit 12 determines that the resolution is high and does not add a point to the score of the resolution.

In a case of an image having a low resolution, many contour points are detected and thus a straight line tends to be difficult to be detected.

Therefore, the classification unit 12 calculates a ratio of the number of pixels occupied by all the detected straight lines in relation to the number of pixels occupied by all the detected contour lines, and then compares the obtained ratio with a predetermined threshold value Rth2 (for example, 0.5). In a case where the ratio is less than or equal to the threshold value Rth2, the classification unit 12 determines that the resolution is low, and then adds a predetermined point to the score of the resolution. Alternatively, in a case where the ratio is larger than the threshold value Rth2, the classification unit 12 determines that the resolution is high and does not add a point to the score of the resolution.

Further, the classification unit 12 may calculate a score of the resolution by using feature amounts for a set of groups of contour points. For example, the classification unit 12 applies blur processing to the binarized image to carry out smoothing of the binarized image, and then detects contour points from the smoothed binarized image. Subsequently, the classification unit 12 applies expansion processing to the detected contour points, thereby joining the contour points adjacent to each other in order to generate a group of contour points. Subsequently, the classification unit 12 removes a group having an area smaller than a predetermined value among the groups of the contour points, and then calculates a feature amount for the set of the remaining groups. For example, an area, a width, and a height of pixels composed of the group of the contour points are used as for the feature amount. In a case where these values are equal to or larger than a predetermined threshold value, the classification unit 12 adds a predetermined point to the score of the resolution. By the above way, the score of the resolution is calculated.

For example, in a case where the total value of the score of the resolution of any of the image areas and of the score of the coverage ratio of the diagonal lines exceeds a predetermined threshold value for guarantee, the classification unit 12 determines that the plan view is a drawing not ensuring the accuracy of the drawing recognition. On the other hand, in a case where the above-mentioned total score for all the image areas is less than the threshold value for guarantee, the classification unit 12 determines that the plan view is a drawing ensuring the accuracy of the drawing recognition.

In addition, in a case of a drawing having a room which is grayed out, it may be considered that the coverage ratio of the diagonal lines is high. Accordingly, by using the score of the coverage ratio of the diagonal lines, a drawing having a grayed out room may be determined as a drawing not ensuring the accuracy of the drawing recognition.

If a drawing having a partition which is drawn by dotted-lines is included in a drawing not ensuring the accuracy of the drawing recognition, the classification unit 12 determines whether or not the partition is a drawing which is drawn by dotted-lines, based on a continuous area included in the binarized image. For example, the classification unit 12 detects a continuous area included in the binarized image, and a continuous area included in the binarized image which had been subjected to the expansion processing. For example, the continuous area may be detected by use of the module, “connectedComponents WithStats” of the Open CV. When the amount of the parts partitioned with dotted-lines becomes larger, the number of the continuous areas after being subjected to the expansion processing tends to increase so as to be larger than the number of the continuous areas before being subjected to the expansion processing. Therefore, the classification unit 12 calculates a ratio of the number of the continuous areas after being subjected to the expansion processing in relation to the number of the continuous areas before being subjected to the expansion processing, and then compares the obtained ratio with a predetermined determination threshold value. When the ratio is equal to or larger than the determination threshold value, the classification unit 12 determines that the plan view is a drawing having a partition drawn by dotted-lines (or a drawing not ensuring the accuracy of the drawing recognition).

If the plan view is determined as a drawing ensuring the accuracy of the drawing recognition at the step S23 (step S24: YES), then the classification unit 12 determines whether or not the plan view includes an oblique room (step S24). At the step S24, firstly, the classification unit 12 detects an object in a white-colored area included in the binarized image. For example, an object(s) in a white-colored area is detected by use of the module, “connectedComponentsWithStats” in the OpenCV. Subsequently, as illustrated in FIG. 7, the classification unit 12 draws a circumscribing rectangle CR1 without considering the rotation and a circumscribing rectangle CR2 considering the rotation, with respect to the object R.

The circumscribing rectangle CR1 without considering the rotation is a rectangle having a side extended along the X axis and a side extended along the Y axis, while circumscribing the object R. The circumscribing rectangle CR2 considering the rotation is a rectangle of which the ratio of the object R occupying in the rectangle becomes the largest among the rectangles circumscribing the object R.

For example, the classification unit 12 determines that the object R is an oblique room when all of the following conditions are satisfied, that is, when the condition where an angle (which is in a range of from 0 degree to 180 degrees) made by any one of the sides of the circumscribing rectangle CR2 and the X axis is equal to or more than the predetermined angle; the condition where the ratio of the area of the object R in relation to the area of the circumscribing rectangle CR1 is equal to or less than the predetermined area ratio; and the condition where the ratio of the number of pixels in the area where the circumscribing rectangle CR2 and the object R overlap with each other in relation to the number of pixels of the circumscribing rectangle CR1 is equal to or less than the predetermined ratio are satisfied. Then, when the number of oblique rooms is equal to or more than the predetermined number, the classification unit 12 determines that the plan view includes an oblique room(s). Alternatively, when the number of oblique rooms is less than the predetermined number, the classification unit 12 determines that the plan view does not include an oblique room.

On the other hand, when it is determined that the plan view is a drawing not ensuring the accuracy of the drawing recognition, at the step S23 (step S23: NO), then, the classification unit 12 performs the process of the step S25 without performing the process of the step S24.

Subsequently, the classification unit 12 outputs the classification result to the recognition unit 14 (step S25). The classification result includes information indicating the type of the plan view (for example, a drawing not ensuring the accuracy of the drawing recognition, a drawing including an oblique room, and a drawing not including an oblique room). By the above way, the classification process of the step S12 is completed.

Subsequently, the dividing unit 13 performs a dividing process (step S13). During the course of the dividing process of the step S13, as illustrated in FIG. 8, the dividing unit 13 extracts a plan view of a building from drawing data when it receives drawing data, vertex coordinates of a frame indicating the plan view, and vertex coordinates of an outer circumference, from the acquisition unit 11 (step S31), and then eliminates characters from the extracted plan view (step S32). The processes of the steps S31, S32 are the same as the processes of the steps S21, S22, and accordingly, the detailed explanations are omitted.

Subsequently, the dividing unit 13 calculates the number-of-dividing N_{div} of the plan view (step S33). The number-of-dividing N_{div} is the number of times for dividing the plan view into two equal parts. At the step S33, firstly, the dividing unit 13 detects an object(s) in a white-colored area included in the binarized image. For example, an object(s) in a white-colored area is detected by use of the module, “connectedComponents WithStats” of the OpenCV.

Then, the dividing unit 13 determines whether or not each of the objects in the detected white-colored area is a room area. It is considered that a room area has a shape close to a rectangular with some extent of width and height. Therefore, the dividing unit 13 determines that the object is not a room area when any of the following conditions is satisfied, that is, when any of the condition where the width or height of the object is equal to or less than the predetermined pixels (for example, 15 pixels); the condition where the ratio of the width to the height of the object or the ratio of the height to the width of the object is equal to or larger than the predetermined value; and the condition where the area of the object is equal to or less than the predetermined pixels (for example, 300 pixels) is satisfied.

When a distance between a center of gravity of a virtual circumscribing rectangle of the object and a center of gravity of the object is separated by a predetermined distance (for example, 30 pixels) or more, the dividing unit 13 may determine that the object is not a room area. The virtual circumscribing rectangle is a rectangle having a width (or length along the X axial) and a height (or length along the Y axial) of the object. Alternatively, when the ratio of the area of the object in relation to the area of the virtual circumscribing rectangle is equal to or less than a predetermined ratio (for example, 0.5), the dividing unit 13 may determine that the object is not a room area.

The dividing unit 13 may determine that an object isolated in a plurality of objects is not a room area. For example, when there is no other object within a predetermined range from the virtual circumscribing rectangle of the object, the dividing unit 13 determines that the object is isolated. For example, the predetermined range is made as a range which is surrounded by a virtual circumscribing rectangle and a rectangle which is separated outward from the periphery of the circumscribing rectangle only by half of the sum of the average width and the average height of all objects.

The emergency stairs, the stairs, and the entrance hall, etc., included in a plan view may be represented as a set of a plurality of objects which are connected to each other and have high similarity. The dividing unit 13 may determine that a plurality of objects which are connected to each other and have a high similarity are not a room area. Specifically, the dividing unit 13 firstly performs a grouping of objects having a high similarity. For example, when the area and the circumferential length of one object are in a range of from about 0.7 times to about 1.3 times of the area and the circumferential length of a different object, it is determined that these objects have a high similarity. The dividing unit 13 applies expansion processing to the all objects to which the grouping had been performed, and connects these objects. Then, when the area of the connected objects is equal to or more than a predetermined multiple (for example, 4.5 times) of the average area of the all objects, the dividing unit 13 determines that none of the objects included in the connected objects is a room area.

Subsequently, the dividing unit 13 removes the object(s) which is determined not to be a room area from the objects in the white-colored area, and then determines that the remaining object(s) as the room area. Followingly, the dividing unit 13 calculates the number-of-dividing N_{div} such that each divided drawing includes a room(s) having the predetermined reference number of rooms N_{ref}. Specifically, at first, the dividing unit 13 calculates the ideal number-of-divided drawings Na by using the number of objects of the room area Nᵣₒₒₘ and the reference number of rooms N_{ref}, as shown in the mathematical formula (1). In this case, the function “int (x)” is made to truncate a decimal point of x so as to return an integer.

$$\begin{matrix}[ Math . 1 ] & \\ {N}_{d} = ( \frac{{N}_{room}}{{N}_{ref}} ) + 1 & ( 1 )\end{matrix}$$

Subsequently, the dividing unit 13 calculates the number-of-dividing N_{div} from the ideal number-of-divided drawings Na as shown in the mathematical formula (2). In this case, the function “round (x)” is made to perform a processing of rounding the number of x so as to obtain an even number closest to x that is equal to or more than x, and return the result.

$$\begin{matrix}[ Math . 2 ] & \\ {N}_{div} = round ( {log}_{2} {N}_{d} ) & ( 2 )\end{matrix}$$

Subsequently, the dividing unit 13 divides the plan view (step S34). During the course of the step S34, the dividing unit 13 divides the plan view into two equal parts for 2N_{div} times (or the N_{div}-th power of 2). In other words, the dividing unit 13 bisects the plan view for N_{div} times. Consequently, divided drawings are generated. For example, as illustrated in FIG. 9, for the first time of the dividing, the dividing unit 13 sets a dividing line L0 connecting the centers of the two long sides of the plan view P. Subsequently, the dividing unit 13 divides the plan view P based on the dividing line L0 so as to obtain two divided drawings P1, P2 which are overlapped each other by a predetermined number of pixels. For example, the dividing unit 13 divides the plan view P so that each of the drawings P1, P2 includes an area having a predetermined amount of pixels including the dividing line L0 along the long side direction.

For the second time of the dividing, the dividing unit 13 sets a dividing line L1 connecting the centers of the two long sides of the plan view P1. Subsequently, the dividing unit 13 divides the plan view P1 based on the dividing line L1 so as to obtain two divided drawings P11, P12 which are overlapped each other by a predetermined number of pixels. Similarly, the dividing unit 13 sets a dividing line L2 connecting the centers of the two long sides of the plan view P2. Subsequently, the dividing unit 13 divides the plan view P2 based on the dividing line L2 so as to obtain two divided drawings P21, P22 which are overlapped each other by a predetermined number of pixels. Hereinafter, the same dividing process is repeated until reaching the number-of-dividing of N_{div}.

Followingly, the dividing unit 13 outputs the divided drawings to the recognition unit 14 (step S35). In a case where the number-of-dividing N_{div} is 0, the plan view is not divided. In such a case, the dividing unit 13 outputs the plan view as the divided drawing to the recognition unit 14. By the above way, the dividing process of the step S13 is completed.

Subsequently, the recognition unit 14 performs a recognition process (step S14). During the course of the step S14, the recognition unit 14 receives the classification result from the classification unit 12, and when the recognition unit 14 receives the divided drawings from the dividing unit 13, it selects one recognition model according to the type of the plan view among a plurality of recognition models. Followingly, the recognition unit 14 inputs the divided drawings to the selected recognition model one by one, and obtains recognition results of the divided drawings from the recognition model.

As illustrated in FIG. 10, the recognition unit 14 includes a recognition model M1 and a recognition model M2. The recognition model M1 is a model for recognizing a plan view including an oblique room. The recognition model M2 is a model for recognizing a plan view not including an oblique room. In a case where the classification-result indicates a drawing including an oblique room, the recognition unit 14 selects the recognition model M1 and inputs the divided drawings to the recognition model M1. Subsequently, the recognition unit 14 obtains the recognition results of the divided drawings from the recognition model M1. On the other hand, in a case where the classification-result indicates a drawing not including an oblique room, the recognition unit 14 selects the recognition model M2 and inputs the divided drawings to the recognition model M2. Subsequently, the recognition unit 14 obtains the recognition results of the divided drawings from the recognition model M2.

Followingly, the recognition unit 14 generates the recognition result of the plan view by summing the recognition results of the respective divided drawings. When a plan view as illustrated in FIG. 11 is used as the recognition result, the recognition unit 14 may recombine the divided drawings into a single plan view, or the recognition unit 14 may use the original plan view as it is. Then, the recognition unit 14 outputs the recognition result of the plan view to the output unit 15.

In a case where the recognition result indicates that the plan view is a drawing not ensuring the accuracy of the drawing recognition, the recognition unit 14 does not perform the recognition processing. In such a case, the recognition unit 14 outputs the recognition result of the plan view indicating that it is not capable of ensuring the accuracy, to the output unit 15.

Subsequently, the output unit 15 outputs the recognition result of the plan view (step S15). At the step S15, the output unit 15 outputs (or transmits) the recognition result of the plan view to a terminal device of a user, upon receiving the recognition result of the plan view from the recognition unit 14. For example, the output unit 15 sends an email containing a URL (or Uniform Resource Locator) for displaying the recognition result of the plan view to the terminal device of the user. For example, when the user clicks the URL on the terminal device, the recognition result of the plan view is made to be displayed.

As illustrated in FIG. 11, the recognition result of the plan view may be displayed by superimposedly displaying the elements included in the plan view with the element IDs on the plan view. Also, as illustrated in FIG. 12, the recognition result may be displayed in a table form. For example, the element ID, the drawing name, the element type, the detailed classification, the integration target, the predicted value and the unit are displayed for each of the elements.

In a case where the recognition result of the plan view indicates that it is not capable of ensuring the accuracy, the output unit 15 notifies the terminal device of the user that the selected plan view is exempt from the objects of support. For example, the output unit 15 notifies that it is not related to the objects of support, by e-mail. By the above way, a series of processings of the drawing recognition method are completed. Incidentally, the step S13 may be performed before the step S12. Alternatively, the step S13 may be performed in parallel with the step S12.

According to the drawing recognition system 10 and the drawing recognition method described above, the plan view is divided based on the number of rooms included in the plan view, and the elements included in the plan view are made to be recognized based on the divided drawings. By the configuration, the variation in the number of rooms included in the divided drawing may be suppressed because the plan view is divided by considering the number of rooms even in the case of the plan view of the building which is different in scale. Therefore, it is possible to improve the recognition accuracy of the elements included in the divided drawings. As a result, it becomes possible to improve the recognition accuracy of the plan view of the building.

Specifically, the dividing unit 13 divides the plan view such that the number of rooms included in the dividing drawing is equal to or less than the reference number of rooms N_{ref}. Therefore, even if the plan view includes a plurality of rooms, the divided drawing is made to include a room(s) having the number of rooms that is less than or equal to the reference number of rooms N_{ref}. Accordingly, even in the case of the plan view of the building which is different in scale, variations in the number of rooms included in the divided drawing may be suppressed. As a result, it becomes possible to improve the recognition accuracy of the plan view of the building.

The recognition unit 14 includes the recognition models which had been generated by carrying out machine learning using a plurality of plan views as learning data. In this configuration, it is possible to improve the recognition accuracy of the plan view of the building by carrying out the learning processes of the recognition models with a sufficient amount of plan views.

There are various types (or characteristics) of plan views such as a plan view including an oblique room and a plan view not including an oblique room. In a case of the configuration in which these plan views are made to be recognized by use of a general-purpose recognition model, there is a possibility that the recognition accuracy is lowered. On the other hand, with respect to the recognition model, in the case of the drawing recognition system 10, the recognition unit 14 is provided with a plurality of recognition models corresponding to a plurality of types with which plan views are capable of being classified. In this case, the recognition unit 14 selects one recognition model, among a plurality of the recognition models, according to the type of the plan view of the recognition object, and generates the recognition result of the plan view by use of the selected recognition model. In other words, one or a plurality of elements included in the divided drawing are recognized by using the recognition model corresponding to the type of the plan view. By the configuration, it is possible to improve the recognition accuracy of the plan view in comparison to the configuration in which a plurality of types of plan views are made to be recognized by using a general-purpose recognition model.

The classification unit 12 determines whether the plan view is a drawing ensuring the accuracy of the drawing recognition or a drawing not ensuring the accuracy of the drawing recognition. If a plan view is determined as a drawing not ensuring the accuracy of the drawing recognition, the recognition unit 14 does not carry out the recognition process of elements included in the plan view. As a result, one or a plurality of drawings not ensuring the accuracy of the drawing recognition are excluded from the recognition objects, and accordingly, it is possible to avoid decline in the drawing recognition of the plan view.

If a plan view is determined as a drawing not ensuring the accuracy of the drawing recognition, the output unit 15 outputs information indicating that it is exempt from the objects of support of the drawing recognition. For example, a user may be made to be recognized that the plan view is not subject to the objects of support of the drawing recognition, by notifying the user of information indicating that it is exempt from the objects of support of the drawing recognition.

The dividing unit 13 generates a binarized image by binarizing the plan view, and then calculates the number of rooms based on an object(s) in a white-colored area(s) included in the binarized image. By the configuration, the number of rooms is obtained by performing image processing on the plan view. As a result, divided drawings may be generated from the plan view without using other information.

Please note that the drawing recognition system and the drawing recognition method according to the present disclosures are not limited to the above-mentioned embodiments.

For example, the drawing recognition system 10 may not be always provided with the classification unit 12. In such a case, the recognition unit 14 generates a recognition result of a plan view by use of a common recognition model.

The drawing recognition application may be configured such that a user is allowed to input a classification. In this case, the drawing recognition system 10 may not be provided with the classification unit 12. Alternatively, a user may be allowed to input a type different from that of a plan view classified by the classification unit 12.

For example, a user may input information indicating that a plan view is corresponding to a plan view of a house, or a plan view excluding a house, in the drawing recognition application. In such a case, the recognition unit 14 selects a recognition model corresponding to the classification inputted by the user, among a plurality of recognition models, and then generates a recognition result of the plan view by use of the selected recognition model.

The recognition unit 14 may recognize one or a plurality of elements included in a plan view by carrying out image analysis instead of using the recognition models.

The classification unit 12 may not determine whether the plan view is a drawing ensuring the accuracy of the drawing recognition or a drawing not ensuring the accuracy of the drawing recognition. In such a case, the recognition unit 14 executes the drawing recognition to all plan views as the recognition objects.

### EXPLANATION OF REFERENCE NUMERALS

10 . . . Drawing recognition system, 11 . . . Acquisition unit, 12 . . . Classification unit, 13 . . . Dividing unit, 14 . . . Recognition unit, 15 . . . Output unit, M1 . . . Recognition model, M2 . . . Recognition model.

1. A drawing recognition system comprising:
an acquisition unit for acquiring data of a drawing including a plan view of a building;
a dividing unit for generating divided drawings by dividing the plan view based on a number of rooms included in the plan view;
a recognition unit for generating a recognition result of the plan view by recognizing an element included in the plan view based on the divided drawings; and
an output unit for outputting the recognition result of the plan view.

2. The drawing recognition system according to claim 1, wherein the recognition unit is provided with a recognition model that is generated by carrying out machine learning using a plurality of plan views as learning data, and
wherein the recognition model is configured to receive the divided drawings and to output recognition results of the divided drawings.

3. The drawing recognition system according to claim 2, further comprising a classification unit for classifying the plan view into one of a plurality of types,
wherein the recognition unit includes a plurality of recognition models corresponding to the plurality of types, as the recognition model, and
wherein the recognition unit is configured to select a recognition model from among the plurality of recognition models according to the type of the plan view, and to generate the recognition result of the plan view by use of the selected recognition model.

4. The drawing recognition system according to claim 3, wherein the classification unit determines whether the plan view is a drawing ensuring accuracy of drawing recognition or a drawing not ensuring accuracy of drawing recognition; and
wherein if the plan view is determined to be a drawing not ensuring accuracy of drawing recognition, the recognition unit refrains from recognizing an element included in the plan view.

5. The drawing recognition system according to claim 4, wherein if the plan view is determined to be a drawing not ensuring accuracy of drawing recognition, the output unit outputs information indicating that the plan view is not subject to drawing recognition.

6. The drawing recognition system according to claim 1, wherein the dividing unit is configured to generate a binarized image by binarizing the plan view, to detect an object in a white-colored area included in the binarized image, and to calculate the number of rooms based on the object.

7. The drawing recognition system according to claim 1, wherein the dividing unit divides the plan view so that the number of rooms included in each of the divided drawings is equal to or less than a predetermined number.

8. A drawing recognition method comprising:
acquiring data of a drawing including a plan view of a building;
generating divided drawings by dividing the plan view based on a number of rooms included in the plan view;
generating a recognition result of the plan view by recognizing an element included in the plan view based on the divided drawings; and
outputting the recognition result of the plan view.

9. A computer program product residing on a computer readable storage medium having a plurality of instructions stored thereon which, when executed across one or more processors, causes at least a portion of the one or more processors to perform operations comprising:
acquiring data of a drawing including a plan view of a building;
generating divided drawings by dividing the plan view based on a number of rooms included in the plan view;
generating a recognition result of the plan view by recognizing an element included in the plan view based on the divided drawings; and
outputting the recognition result of the plan view.
